(19) United States
(12) Patent Application Publication
(10) Pub. No.: US 2013/0192865 A1
(43) Pub. Date: Aug. 1, 2013

(54) NOISE SUPPRESSION STRUCTURE

(71) Applicants: Eiji Hankui, Tokyo (JP); Koichiro Nakase, Tokyo (JP); Jun Sakai, Tokyo (JP)

(72) Inventors: Eiji Hankui, Tokyo (JP); Koichiro Nakase, Tokyo (JP); Jun Sakai, Tokyo (JP)

(73) Assignee: NEC CORPORATION

(21) Appl. No.: 13/634,782

(22) PCT Filed: Mar. 15, 2011
(86) PCT No.: PCT/JP2011/056012

§ 371 Date: Jan. 17, 2013

(30) Foreign Application Priority Data
Mar. 15, 2010 (JP) 2010-058238

(51) Int. Cl. H05K 9/00

(52) U.S. Cl. CPC H05K 9/0064
USPC 174/32

(57) ABSTRACT

A noise suppression structure of the present invention includes a current control unit provided on a ground layer and controlling current. The current control unit includes: a metal plane that is provided above the ground layer with an interval therebetween; and a short circuit plate that is arranged at one end portion of the metal plane, and connects the metal plane and the ground layer. A notch portion is provided in a portion of the metal plane.

### TECHNICAL FIELD

The present invention relates to a noise suppression structure, which is applied to electronic/electric equipment including a wireless application device such as a portable phone, a wirelessly equipped personal computer, and a portable information terminal, and reduces the effect of electromagnetic interference that occurs between a digital circuit unit and a wireless circuit unit so as to secure a better quality of communication.

### BACKGROUND ART

A wireless application device such as a portable phone and a wirelessly equipped personal computer has been widely used because of its convenience. Recently, thickness reduction or size reduction of the Wireless application device has been ongoing. Further, mounting for a plurality of wireless systems on the Wireless application device has also been ongoing.

FIGS. 19 to 21 illustrate basic configurations of a general portable terminal in a wireless application device 30 of the conventional art. FIG. 19 is a perspective view illustrating the entire configuration of the portable terminal. FIG. 20 is a perspective view illustrating only a noise suppression structure 40. FIG. 21 is a side view of the noise suppression structure 40 illustrated in FIG. 20.

In the wireless application device 30, at least an antenna unit 21, a wireless circuit unit 22, and a digital circuit unit 23 are mounted on a printed substrate 24. The antenna unit 21 transmits/receives radio waves for communicating with a base station or the like. The wireless circuit unit 22 processes a signal to be transmitted from the antenna unit 21 or a signal received by the antenna unit 21. The digital circuit unit 23 processes a digital signal for processing data.

A ground layer 43 is disposed on an internal layer of the printed substrate 24. The ground layer 43 becomes the common ground of the digital circuit unit 23 and the wireless circuit unit 22.

The noise control configuration 40 to be described later is mounted on the printed substrate. The noise control configuration 40 suppresses electromagnetic interference that occurs between the digital circuit unit 23 and the wireless circuit unit 22.

Although not illustrated, a signal layer and a power supply layer are also formed on the internal layer of the printed substrate 24. A pattern for transferring a signal corresponding to each purpose such as a digital signal or an analog signal, or the like is formed on the signal layer and the power supply layer.

As can be seen with reference to FIG. 19, the wireless circuit unit 22 and the digital circuit unit 23 coexist on the same board in the wireless application device 30. Actually, the wireless circuit unit 22 and the digital circuit unit 23 are densely mounted in the wireless application device 30. Thus, electromagnetic noise generated from the digital circuit unit 23 is mixed into the antenna unit 21 or the wireless circuit unit 22 in the board as described above, so that electromagnetic interference occurs and affects reception characteristics of an antenna.

The digital circuit unit 23 handles a clock signal of which the basic wave has about several 10 MHz or several 100 MHz, a data bus signal, or the like. If noise consistent with a reception band (800 MHz band, 2 GHz band, or the like) of the antenna among noise in a high frequency band of the signal as described above is mixed into the wireless circuit unit 22 or the antenna unit 21, wireless characteristics such as antenna reception sensitivity are degraded.

In addition, when a current from the antenna unit 21 is mixed into the digital circuit unit 23, mixing of a transmission wave and a digital signal occurs as noise.

As described above, a current generated from the digital circuit unit 23 and the wireless circuit unit 22 or the antenna unit 21 sometimes acts as noise in the wireless application device 30. This current is mixed from one circuit unit into another circuit unit via the common ground layer 43. That is, mixing of a noise current from the digital circuit unit 23 into the wireless circuit unit 22 (or the antenna unit 21) and mixing of a current from the wireless circuit unit 22 (or the antenna unit 21) into the digital circuit unit 23 occur.

Electromagnetic interference by mixing of noise in two directions between the digital circuit unit 23 and the wireless circuit unit 22 as described above tends to be more noticeable according to size reduction, thickness reduction, or mounting of a plurality of wireless systems. In order to secure a better quality of communication, it is desirable to suppress electromagnetic interference between the digital circuit unit 23 and the wireless circuit unit 22 to be lower. In addition, because a frequency band tends to be expanded according to mounting of a plurality of wireless systems in the wireless application device 30, the widening of a frequency band (including multi-frequency), which suppresses electromagnetic interference, is desirable.

In order to suppress electromagnetic interference, for example, a noise control configuration focused on a current flowing over a metal surface is proposed in Patent Document 1 (Japanese Unexamined Patent Application, First Publication No. 2002-314491).

In a portable wireless application device disclosed in Patent Document 1, a current control mechanism unit, which suppresses electromagnetic coupling between two circuit units within a printed substrate, is mounted to separate a wireless circuit unit and a digital circuit unit from each other. This current control mechanism unit provides metal planes at the upper surface and lower surface in parallel so as to sandwich the ground layer. A via hole array is formed in a linear shape at the positions of both sides of the metal planes and at positions separated by desired intervals from the end portions of the metal planes in a direction that couples the wireless circuit unit and the digital circuit unit.

In Patent Document 1, the noise suppression structure is disposed with respect to the upper and lower layer of a metal plane (ground). Here, since the structure and principle of the noise suppression structure of the upper layer and lower layer are the same, only the case of disposing the same noise suppression structure on the upper layer shall be described.

As can be seen with reference to FIGS. 20 and 21, the noise suppression structure 40 has a metal plane 41 formed parallel to a ground layer 43 and a short circuit plane 42 formed on an end of the metal plane 41 in order to suppress a current that flows through a ground layer of a board. It is configured as a resonator having a length of the metal plane 41 set at λ/4, which is ¼ of a wavelength λ of a desired frequency f. Thus, an open end at a right end electrically acts as an open end, and input impedance has a high value. When the impedance is high, the current In that flows through the ground is hindered from flowing. As a result, the mixing in of electromagnetic noise from one side to the other side, that is to say, “digital circuit unit 23 side Ds→wireless circuit unit 22 side Ws” is suppressed.

### PRIOR ART DOCUMENT

### Patent Document

[Patent Document 1] Japanese Unexamined Patent Application, First Publication No. 2002-314491

### SUMMARY OF THE INVENTION

### Problem to be Solved by the Invention

In the noise suppression structure 40 shown in Patent Document 1, there is provided a configuration of a resonator in which a metal plane is configured to enclose a current that flows through the ground layer of the board, a distal end side serves as a short circuit plane, and a length of the metal plane serving as a transmission path is set at λ/4 (λ: wavelength). According to this configuration, the input impedance has a high value at an open end side. In addition, in the configuration as described above, it is difficult for a current from a line connected to the open end side to flow toward a line connected to the distal end side. That is, mixing of electromagnetic noise from one side into the other side is suppressed.

However, in the noise suppression structure 40 shown in the conventional art, the number of frequencies corresponding to λ/4 is one because the metal plane serving as the transmission path has a single length. Thus, a wireless application device in which a plurality of wireless systems are mounted has a problem in multi-frequency correspondence and the widening of a frequency band.

That is, the above-described noise suppression structure 40 is effective for a single frequency serving as a target, but does not sufficiently cope with band widening or multi-frequency correspondence. In this point, it is desirable to improve a noise suppression structure.

The present invention has been made in view of the above-described circumstances. An exemplary object of the present invention is to provide a noise suppression structure capable of reducing the effect of electromagnetic interference that occurs between a digital circuit unit and a wireless circuit unit and sufficiently coping with band widening or multi-frequency correspondence.

### Means for Solving the Problem

In order to solve the above-described problem, a noise suppression structure of the present invention includes a current control unit provided on a ground layer and controlling current. The current control unit includes: a metal plane that is provided above the ground layer with an interval therebetween; and a short circuit plate that is arranged at one end portion of the metal plane, and connects the metal plane and the ground layer. A notch portion is provided in a portion of the metal plane.

### Effect of the Invention

In a noise suppression structure of a current control unit according to the present invention, a notch portion is provided in a portion of a metal plane of the current control unit. According to this configuration, transmission paths corresponding to at least two frequencies can be formed on one metal plane. Thereby, for example, the effect of suppression can be obtained in at least two frequency bands for a noise current that is generated from a digital circuit unit, which is one circuit unit, flows through a board and mixed into a wireless circuit unit, which is the other circuit unit, and it is possible to effectively achieve multi-frequency correspondence of a noise suppression frequency.

At this time, for the notch portion formed in the metal plane, a transmission path of a low frequency band side at which a noise level tends to be high may be arranged on outer sides (two sides of a board). According to this arrangement, a higher suppression effect is obtained in two frequency bands for a noise current that is generated from the digital circuit unit, flows through a board and mixed into the wireless circuit unit, and multi-frequency correspondence of a noise suppression frequency is possible.

### BRIEF DESCRIPTION OF THE DRAWINGS

FIG. 1 is a perspective view illustrating a noise suppression structure according to a first exemplary embodiment of the present invention.

FIG. 2 is an exploded perspective view of the noise suppression structure illustrated in FIG. 1.

FIG. 3 is a sectional side view along a length direction of the noise suppression structure illustrated in FIG. 1.

FIG. 4 is a plan view of a metal plane of the noise suppression structure of FIG. 1.

FIG. 5 is a side view illustrating a positional relationship between the noise suppression structure illustrated in FIG. 1, and a digital circuit unit and a wireless circuit unit.

FIG. 6 is a perspective view illustrating a noise suppression structure according to a first modified example of the first exemplary embodiment of the present invention.

FIG. 7 is an exploded perspective view of the noise suppression structure illustrated in FIG. 6.

FIG. 8 is a sectional side view along a length direction of the noise suppression structure illustrated in FIG. 6.

FIG. 9 is a plan view of a metal plane of the noise suppression structure illustrated in FIG. 6.

FIG. 10 is a plan view illustrating a noise suppression structure according to a second modified example of the first exemplary embodiment of the present invention.

FIG. 11 is a plan view illustrating a noise suppression structure according to a third modified example of the first exemplary embodiment of the present invention.

FIG. 12 is a plan view illustrating another form of the noise suppression structure illustrated in FIG. 11.

FIG. 13 is a plan view illustrating a noise suppression structure according to a fourth modified example of the first exemplary embodiment of the present invention.

FIG. 14 is a plan view illustrating another form of the noise suppression structure illustrated in FIG. 13.

FIG. 15 is a plan view illustrating a noise suppression structure according to a fifth modified example of the first exemplary embodiment of the present invention.

FIG. 16 is a perspective view illustrating a noise suppression structure according to the second exemplary embodiment of the present invention.

FIG. 17 is an exploded perspective view of the noise suppression structure illustrated in FIG. 16.

FIG. 18 is a sectional side view along a length direction of the noise suppression structure illustrated in FIG. 16.

FIG. 19 is a perspective view illustrating an example of a noise suppression structure of a conventional art.

FIG. 20 is a perspective view of the noise suppression structure illustrated in FIG. 19.

FIG. 21 is a sectional side view along a length direction of the noise suppression structure illustrated in FIG. 19.

### EMBODIMENTS FOR CARRYING OUT THE INVENTION

### First Exemplary Embodiment

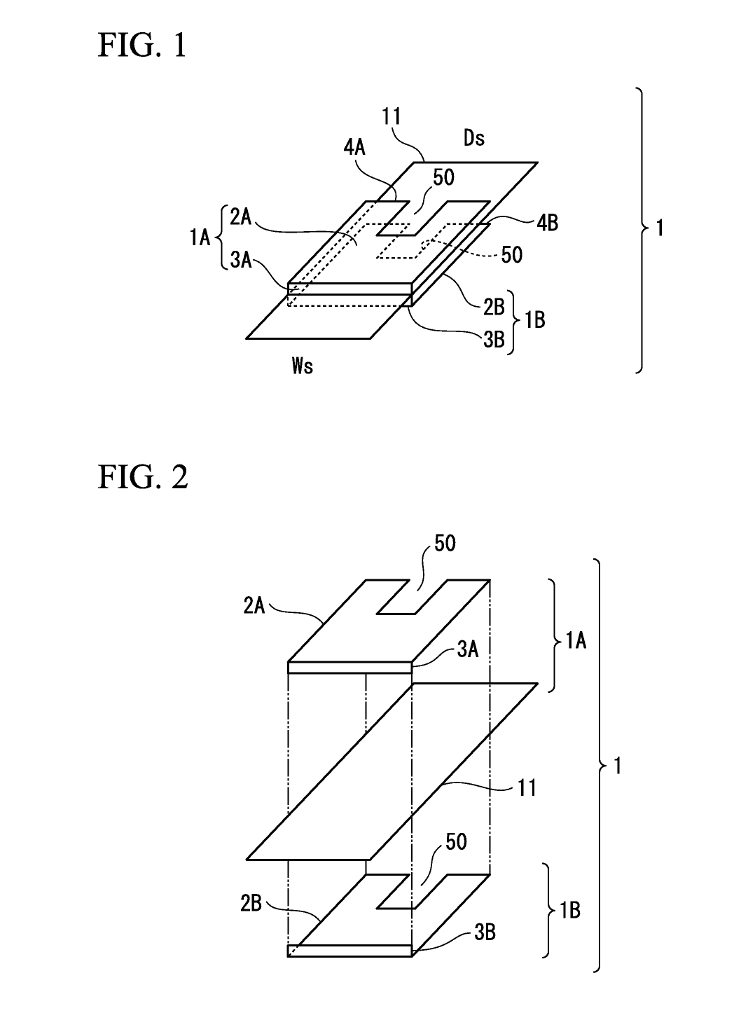

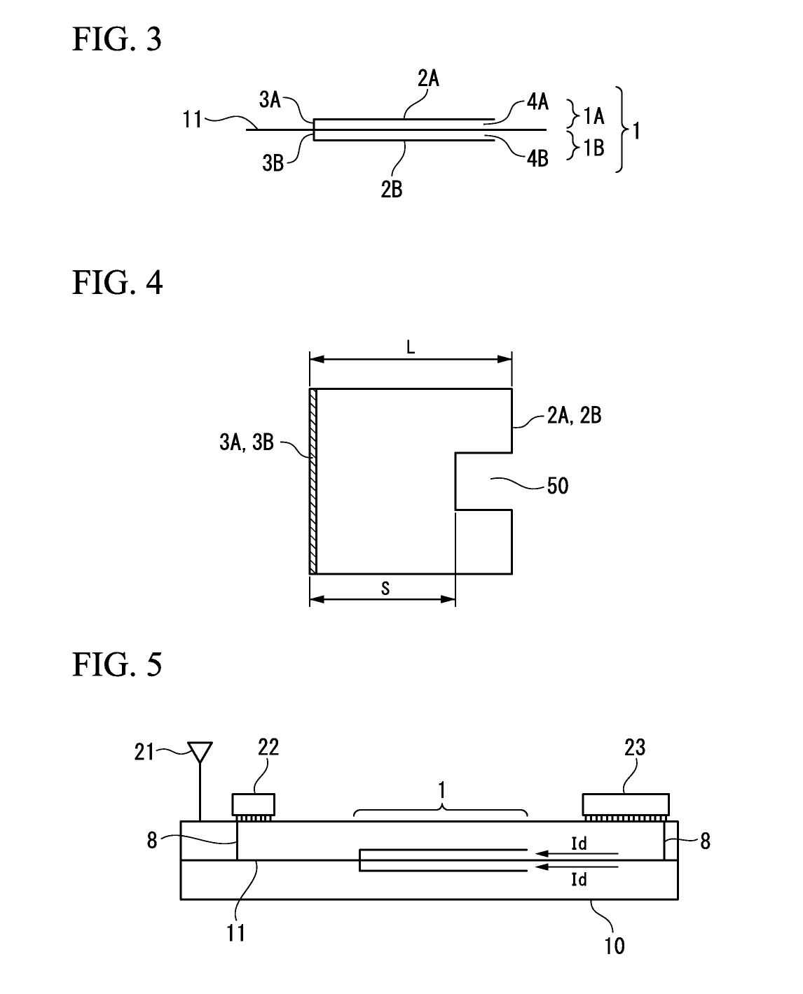

FIGS. 1 to 5 illustrate a noise suppression structure 1 according to a first exemplary embodiment of the present invention. FIG. 1 is a perspective view illustrating the noise suppression structure 1 according to the first exemplary embodiment of the present invention. FIG. 2 is an exploded view of the noise suppression structure 1 illustrated in FIG. 1. FIG. 3 is a side view illustrating the noise suppression structure 1 of FIG. 1. FIG. 4 is a plan view illustrating dimensions of current control units 1A and 1B. FIG. 5 is a side view illustrating an example in which the noise suppression structure 1 is disposed within a board 10 of a wireless application device.

As illustrated in FIG. 5, the noise suppression structure 1 according to the first exemplary embodiment is disposed between a digital circuit unit 23 and a wireless circuit unit 22. The noise suppression structure 1 disposed as described above interrupts electromagnetic coupling between the wireless circuit unit 22 and the digital circuit unit 23, and particularly, prevents noise from being mixed from the digital circuit unit 23 into the wireless circuit unit 22 or an antenna.

Specifically, the current control units 1A and 1B are constituted of metals having the same size in a width direction of the board 10. The noise suppression structure 1 is constituted by the first current control unit 1A disposed at an upper layer side of a ground layer 11 and the second current control unit 1B disposed at a lower layer side between which the ground layer 11 is interposed. According to this configuration, a noise current, which flows through the ground layer 11 of the board 10, is effectively suppressed. These current control units 1A and 1B are disposed to be mutually symmetrical with respect to the ground layer 11. In these current control units 1A and 1B, notch portions 50 serving as uneven surfaces are provided in portions of ends of metal planes (metal plates) 2A and 2B (details will be described later). According to this configuration, multi-frequency correspondence of a noise suppression frequency is achieved and also mixing of currents occurring in the circuit units 22 and 23 at both sides is suppressed.

In the noise suppression structure 1, a multi-layer printed substrate including a plurality of layers is used. Although not illustrated, a dielectric material such as a glass epoxy material is embedded between the layers of the board.

Hereinafter, the noise suppression structure 1 according to the first exemplary embodiment will be described in detail.

The noise suppression structure 1 is constituted of the first and second current control units 1A and 1B. The first current control unit 1A is constituted of the metal plane 2A and a short circuit plate 3A, and is connected to the ground layer 11. The second current control unit 1B is constituted of the metal plane 2B and a short circuit plate 3B, and is connected to the ground layer 11. The first metal plane 2A, the first short circuit plate 3A, the ground layer 11, the second short circuit plate 3B, and the second metal plane 2B are disposed in order from the upper layer.

The rectangular notch portion 50 is formed in a portion of an end (second end) of a side Ds facing the digital circuit unit 23 of the metal planes 2A and 2B. According to this shape, lengths of the metal planes 2A and 2B are partially different when viewed from the side Ds of the digital circuit unit 23.

As will be described later, this is because a noise suppression frequency is set to be multi-frequency. In addition, the notch portion 50 is provided in a concave shape in the vicinity of the center of the metal plane. The length of the metal plane is short in a region of the central portion (indicated by a reference symbol S), and long in regions corresponding to two sides of the board 10, which are outer sides, (indicated by a reference symbol L), when viewed from the side Ds of the digital circuit unit 23 as illustrated in FIG. 4.

Each of the short circuit plates 3A and 3B actually constituted by a plurality of via holes arranged in a row in its region. In this configuration, because a spacing between adjacent via holes has a narrow pitch that is sufficiently small with respect to a wavelength, it can be regarded as an electrically short-circuit state. Here, an array of a plurality of via holes arranged with the narrow pitch as described above is referred to as a “short circuit plate.” Further, the via hole used here is a configuration in which a conductive layer is formed around an air hole. This via hole, which passes through this metal pattern, is electrically connected to the metal pattern.

The metal plane 2A constituting the first current control unit 1A and the metal plane 2B constituting the second current control unit 1B are constituted of metal patterns. Sizes of width directions of the metal planes 2A and 2B are the same as a size of a width direction of the board 10. The metal plane 2A is formed at the upper layer of the ground layer 11. The metal plane 2B is formed at the lower layer of the ground layer 11. The ground layer 11 is interposed between the metal plane 2A and the metal plane 2B.

The short circuit plates 3A and 3B are provided at ends of the metal planes 2A and 2B of sides that are opposite sides having the notch portions 50. The short circuit plates 3A and 3B are connected to the metal planes 2A and 2B and the ground layer 11. Thus, the first current control unit 1A forms one pair of transmission lines by the metal plane 2A and the ground layer 11.

That is, a short circuit end (short circuit plane) is formed at one end (first end) of the metal plane 2A. This short circuit end is constituted of the short circuit plate 3A. An open end 4A is formed at the other end (second end) of the metal plane 2A. This open end 4A is constituted of an opening between the metal plane 2A and the ground layer 11.

Likewise, the second current control unit 1B also forms transmission lines by the metal plane 2B and the ground layer 11. An open end 4B is formed at one end of the metal plane 2B, and a short circuit plane is formed by the short circuit plate 3B at the other end.

According to this configuration, in the current control units 1A and 1B, the open ends 4A and 4B are directed toward the side Ds of the digital circuit unit 23, and the short circuit plates 3A and 3B are directed toward a side As or Ws of an antenna unit 21 or the wireless circuit unit 22.

While the short circuit plates 3A and 3B of the first and second current control units 1A and 1B are formed of via holes having a narrow pitch as described above, each via hole may simultaneously pass through the metal planes 2A and 2B.

In an actual wireless application device, the board 10 or the like is included in a housing, but the illustration of the housing is omitted here. Likewise, although not illustrated, a liquid crystal display, operation buttons, or an operation keyboard is mounted on the equipment.

Next, principles and operations related to noise suppression of the current control units 1A and 1B illustrated in FIGS. 1 to 4 will be described.

A length along a longitudinal direction of the metal plane 2A or 2B is denoted by “L.” A length along the longitudinal direction of the metal plane 2A or 2B excluding the notch portion 50 positioned in the vicinity of the center is denoted by “S.” In the case of this configuration, there is a relationship of “L>S.” In addition, “L” and “S” are each set at resonant lengths of ¼ wavelength with respect to desired different frequencies f₁ and f₂. That is, L=λ₁/4 and S=λ₂/4 are set (wavelengths λ₁ and λ₂ are wavelengths of the frequencies f₁ and f₂, respectively).

In general, in a transmission line of which one end is electrically short-circuited, a position separated by ¼ wavelength is an open end. In the position, input impedance has a high value (infinite ideally). A noise current flows through the ground layer 11 of the board 10. In the case of this configuration, corresponding to this, the current control units 1A and 1B of which distal ends are short-circuited are provided. In addition, the length of a metal plane corresponding to a transmission line is set to the length of ¼ wavelength. Thus, the impedance at the open ends 4A and 4B has a high value.

Thus, the noise current flowing from the side Ds of the digital circuit unit 23 to the side Ws of the wireless circuit unit 22 is hard to flow due to the effect of high impedance at the open ends 4A and 4B. As a result, mixing of noise is suppressed.

Further, the noise suppression structure 1 of the current control units 1A and 1B according to this exemplary embodiment forms transmission paths resonant at two frequencies in one metal plane 2A or 2B. According to this configuration, multi-frequency correspondence of a noise suppression frequency is achieved. That is, the notch portion 50 is provided in the vicinity of the central portion of the metal plane 2A or 2B. According to this configuration, transmission paths corresponding to lengths L of the original metal planes 2A and 2B are formed on outer sides (two sides of the board), and a transmission path corresponding to a length S that is shorter by the amount of the notch portion 50 is formed in the vicinity of the central portion.

The metal planes 2A and 2B of the outer sides corresponding to the transmission paths of the length L (=λ₁/4) resonate at the frequency f₁. The metal planes 2A and 2B of the central portions corresponding to the transmission paths of the length S (=λ₂/4) resonate at the frequency f₂. Thus, this configuration effectively operates for two frequency components. Thus, it is possible to obtain the effect of suppression in a wide hand by corresponding to multi-frequency for a current that flows through the ground layer 11 of the board 10 using this configuration.

In the noise suppression structure 1 of the current suppression units 1A and 1B according to this exemplary embodiment, a transmission path having a longer length L is formed on outer sides of the metal plane 2A or 2B. The reason for this will be described below.

In general, a frequency for use in the wireless application device is usually in a band of several MHz to several GHz, and a high-frequency band such as an 800 MHz band or a 2 GHz band is used in a portable phone or the like. In this frequency band, a standing wave is generated on the ground layer 11 of the board 10, and a current tends to flow through edges of two sides. In addition, when the attenuation of a harmonic component of noise is considered, a lower frequency band side of 800 MHz tends to have a higher noise level than a higher frequency band side such as 2 GHz.

Thus, in this configuration, the metal planes 2A and 2B of the lengths L corresponding to transmission paths for a low frequency band are disposed on outer sides for the purpose of effectively suppressing a current of the low frequency band side that tends to flow through the edge of the board 10 and tends to have a high level.

FIG. 5 illustrates functions of the open ends 4A and 4B for a noise current when the above-described current control units 1A and 1B are configured within the board 10 of the wireless application device.

The ground layer 11 of the digital circuit unit 23 and the wireless circuit unit 22 is commonly shared via a signal pattern 8. As can be seen with reference to FIG. 5, the open ends 4A and 4B directed toward the digital circuit unit 23 side Ds have high impedance for a noise current Id that is mixed from the digital circuit unit 23 side Ds into the wireless circuit unit 22 side Ws via the ground layer 11. According to this effect, it is difficult for the noise current Id to flow. As a result, mixing of the noise current Id generated from the digital circuit unit 23 into the wireless circuit unit 22 or the antenna 21 is suppressed.

In the noise suppression structure 1 according to this exemplary embodiment as described above, the notch portions 50 are provided in the metal planes 2A and 2B of the current control units 1A and 1B. According to this configuration, transmission paths corresponding to at least two frequencies can be formed on one metal plane 2A or 2B. Thereby, for example, the effect of suppression is obtained in at least two frequency bands for a noise current that is generated from the digital circuit unit 23, which is one circuit unit, flows through the board and mixed into the wireless circuit unit 22, which is the other circuit unit. Consequently, it is possible to effectively achieve multi-frequency correspondence of a noise suppression frequency according to the noise suppression structure 1 according to this exemplary embodiment.

Although the open ends 4A and 4B of the current control units 1A and 1B are directed toward the digital circuit unit 23 side Ds in the above-described first exemplary embodiment, it is not limited thereto. For example, the open ends 4A and 4B may be disposed toward the wireless circuit unit 22 side Ws. Thereby, it is possible to effectively suppress a noise current that is generated from the wireless circuit unit 22, flows through the board and mixed into the digital circuit unit 23, which is the other circuit unit.

### FIRST MODIFIED EXAMPLE

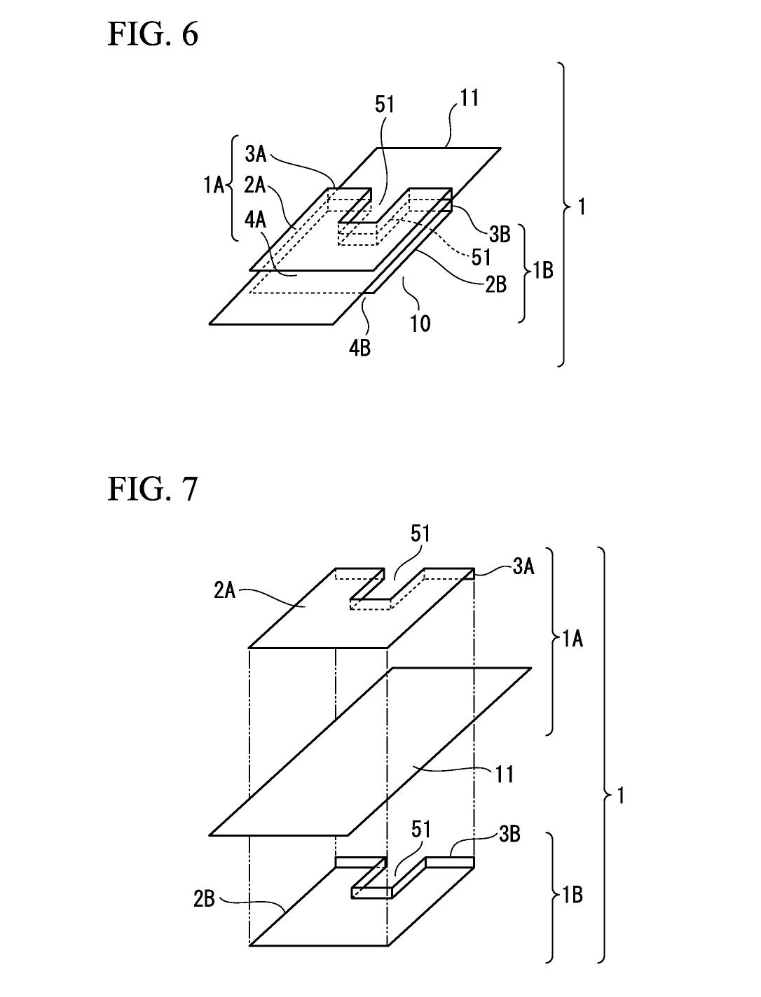

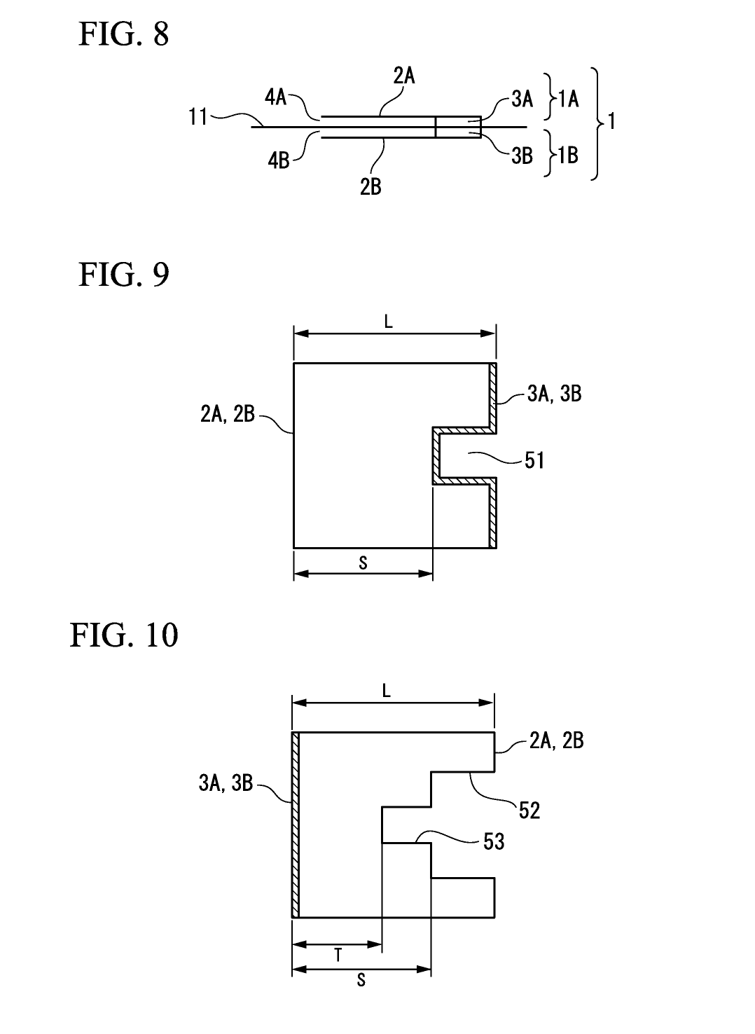

FIGS. 6 to 9 illustrate a noise suppression structure 1 according to a first modified example of the first exemplary embodiment according to the present invention. FIG. 6 is a perspective view illustrating the entire noise suppression structure 1 according to the first modified example of the first exemplary embodiment of the present invention. FIG. 7 is an exploded view of the noise suppression structure 1 illustrated in FIG. 6. FIG. 8 is a side view of the noise suppression structure 1 illustrated in FIG. 6. FIG. 9 is a plan view illustrating dimensions of current control units 1A and 1B.

The current control units 1A and 1B shown in the first modified example are different from those of the above-described first exemplary embodiment in terms of positions of notch portions 51 provided in metal planes 2A and 2B. The current control units 1A and 1B shown in the first modified example are the same as the above-described configurations (the configurations of the first exemplary embodiment) in terms of a layer configuration within the board 10 and in that the notch portions are provided in portions of ends of the metal planes 2A and 2B.

FIG. 9 illustrates the metal planes 2A and 2B constituting the current control units 1A and 1B. The notch portions 51 are provided in the metal planes 2A and 2B as in the above-described first exemplary embodiment. In this configuration, short circuit plates 3A and 3B are formed along the rectangular notch portions 51. As can be seen with reference to FIG. 9, a transmission path corresponding to a resonant frequency f₁ is provided in a region of an outer side having a length L (=λ₁/4). In addition, a transmission path corresponding to a resonant frequency f₂ is provided in a region of a central portion having a length S (=λ₂/2). Thus, when this first modified example is compared to the first exemplary embodiment, positions of the short circuit plates 3A and 3B are different. However, in this first modified example, the length of the transmission path is set to a length of ¼ wavelength. Consequently, high impedance is obtained in two frequency bands at sides of Open ends 4A and 4B. As a result, the effect of suppression in a wide band by corresponding to multi-frequency for a noise current mixed from the sides of the open ends 4A and 4B can be sufficiently obtained.

This configuration is suitable when a component that is not affected by the effect of noise is mounted in a position of the notch portion 51 such as when a component is mounted immediately behind a short circuit plate.

### SECOND MODIFIED EXAMPLE

FIG. 10 illustrates metal planes 2A and 2B of current control units 1A and 1B according to a second modified example of the first exemplary embodiment according to the present invention. By devising shapes of the metal planes 2A and 2B, noise suppression by corresponding to multi-frequency and widening of a frequency band is possible.

In the configuration illustrated in FIG. 10, additional multi-frequency correspondence is implemented by combining two notch portions 52 and 53. In this modified example, the rectangular notch portions 52 and 53 having different widths and lengths overlap. That is, the notch portion 53 having a narrow width is provided in the notch portion 52 having a wide width. According to this configuration, it is possible to form line lengths in three paths (L>S>T) when viewed from sides of open ends 4A and 4B as illustrated in FIG. 10. In this case, because the lengths L, S, and T each correspond to λ/4 of a desired frequency, noise suppression for three frequencies is possible.

As in the first modified example, the notch portion 52 or 53 of this second modified example may be provided in either of sides of short circuit plates 3A and 3B of the metal planes 2A and 2B and the sides of the open ends 4A and 4B. This is the same as in the following modified examples and exemplary embodiments.

### THIRD MODIFIED EXAMPLE

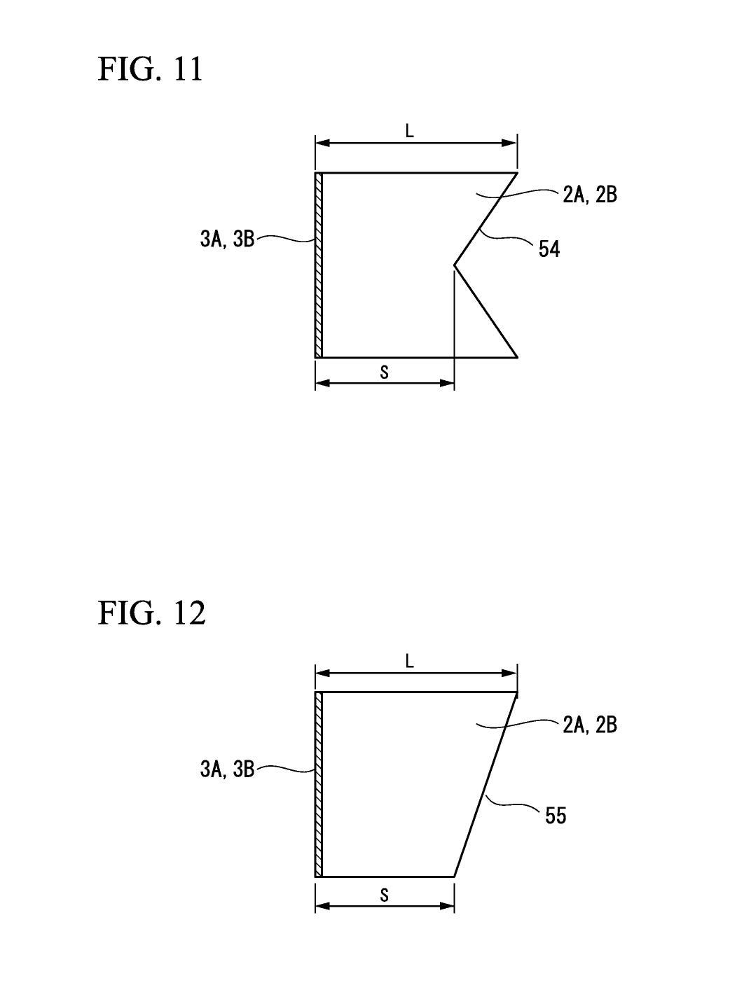

FIG. 11 illustrates metal planes 2A and 2B of current control units 1A and 1B according to a third modified example of the first exemplary embodiment according to the present invention. There are characteristics in shapes of the metal planes 2A and 2B. In the third modified example, as illustrated in FIG. 11, inclined notch portions 54 are provided in central portions of ends of the metal planes 2A and 2B. In an example illustrated in FIG. 11, the notch portion 54 is formed in a V shape. In the above-described first exemplary embodiment and its first and second modified examples, because the notch portions 50 to 53 are rectangular, resonant lengths are two steps of lengths L and S. On the other hand, in this configuration, the notch portion 54 has a shape which is cut at a tilt. Thus, the resonant length continuously changes between the lengths L and 5, and a frequency at which a length from a short circuit plate becomes ¼ wavelength is continuous. That is, in the first modified example, impedance at the open ends 4A and 4B becomes high only in the case of two frequencies f₁ and f₂ corresponding to the lengths L and S. On the other hand, in this configuration, because the length continuously changes high impedance is obtained in a range of frequencies from f₁ to f₂ according to the change. Thus, this configuration can have a sufficient effect for band widening of a noise suppression frequency.

Although the notch portions 54 of the central portions of the ends of the metal planes 2A and 2B are formed in V shapes in the above-described third modified example, it is not limited thereto. Instead of these, notch portions 55 inclined at a tilt may be formed in ends of the metal planes 2A and 2B so that lengths of the metal planes 2A and 2B continuously change as illustrated in FIG. 12. In this case, band widening for noise suppression within a frequency range (f₁ to f₂) corresponding to lengths L to S is achieved.

### FOURTH MODIFIED EXAMPLE

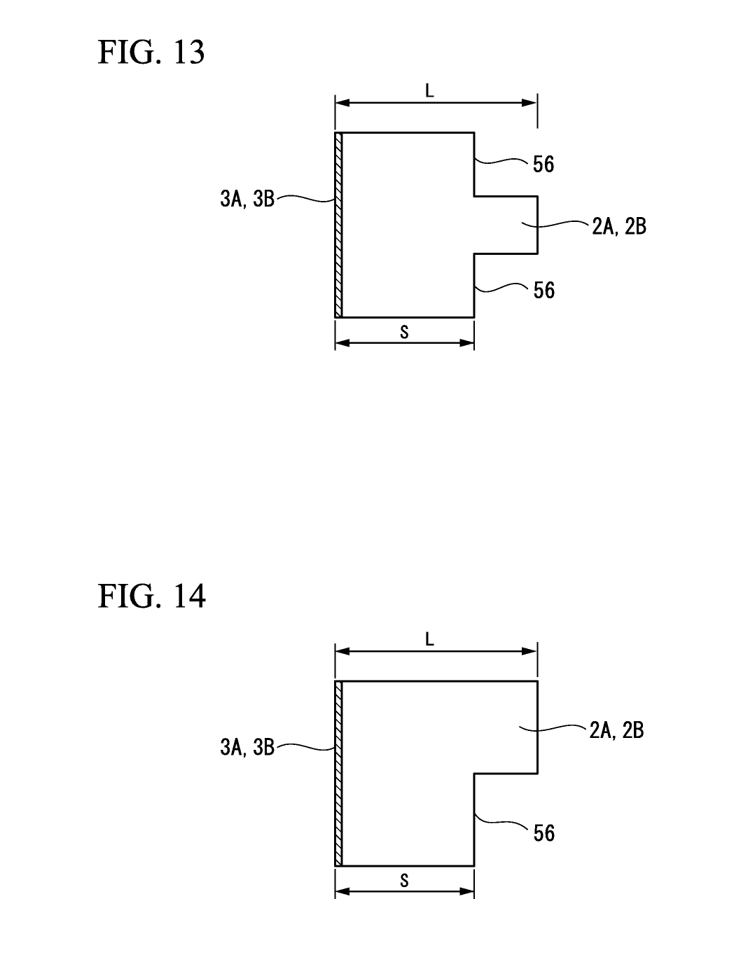

FIG. 13 illustrates metal planes 2A and 2B of current control units 1A and 1B according to a fourth modified example of the first exemplary embodiment according to the present invention. There are characteristics in shapes of notch portions 56 of the metal planes 2A and 2B. In the modified example, the notch portions 56 are provided on two sides of the metal planes 2A and 2B. Thus, in contrast to the cases of the first exemplary embodiment and its first to third modified examples, transmission paths having a short length S are formed on two sides of the metal planes 2A and 2B as illustrated in FIG. 12. In this case, the effect is sufficiently obtained when a noise current of a high frequency band side such as 2 GHz significantly flows through two sides of a board 10.

It is not limited to two notch portions 56 formed on the two sides of the metal planes 2A and 2B as illustrated in FIG. 13. As illustrated in FIG. 14, the notch portions 56 may be formed close to an ends instead of central portions of the metal planes 2A and 2B. According to this configuration, in the metal planes 2A and 2B, a length of one of the two sides becomes L and a length of the other becomes S. In this case, as in the above-described principle, impedance of open ends 4A and 4B becomes high at frequencies (f₁ and f₂) corresponding to the resonant lengths L and S, and multi-frequency correspondence for noise suppression is achieved.

In the noise suppression structure 1 of the current control units 1A and 1B as described above, the notch portions 56 are provided on two sides of the metal planes 2A and 2B. According to this configuration, transmission paths corresponding to two frequencies are formed on one metal plane 2A or 2B. Further, a transmission path of a low frequency band side at which a noise level tends to be high is disposed on outer sides (two sides of the board). Thus, there is an advantage in that the effect of suppression is obtained in two frequency bands for a noise current that is generated from the digital circuit unit 23, flows through the board 10 and mixed into the wireless circuit unit 22, and multi-frequency correspondence of a noise suppression frequency is effectively achieved.

### FIFTH MODIFIED EXAMPLE

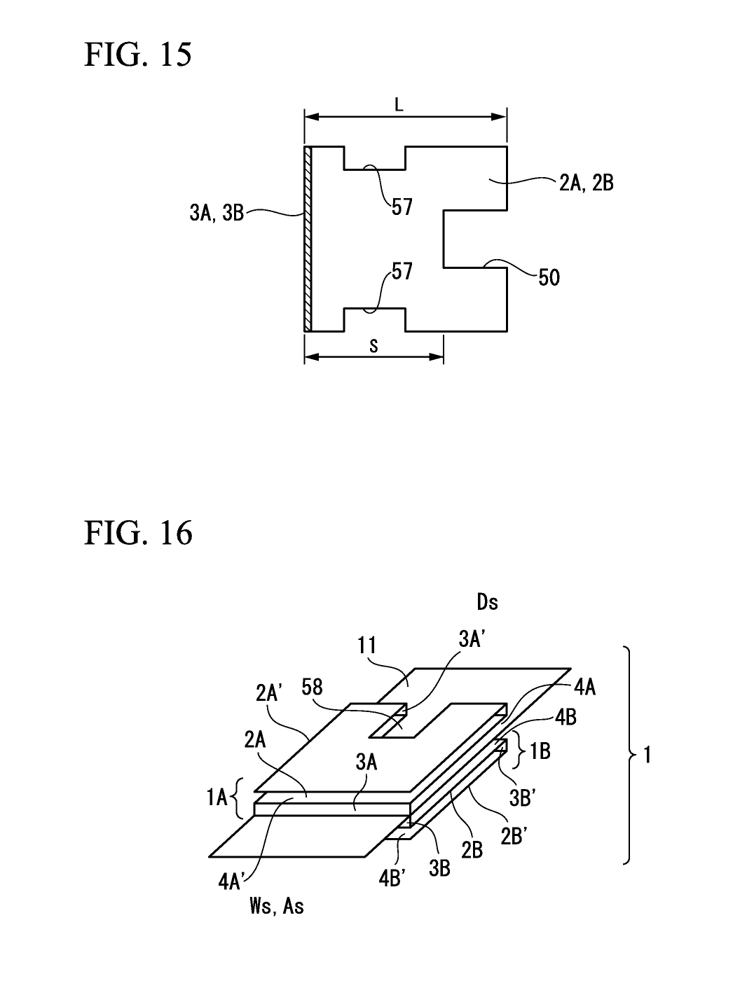

FIG. 15 illustrates metal planes 2A and 2B of current control units 1A and 1B according to a fifth modified example of the first exemplary embodiment according to the present invention. In this modified example, notch portions 57 are provided on two sides of the metal planes 2A and 2B in addition to central portions of the metal planes 1A and 2B facing the wireless circuit unit 22 or the digital circuit unit 23. According to the notch portions 57 provided in two-side portions of the metal planes 2A and 2B as described above, lengths by the amount of the notch portions 57 may be bypassed and the original length (L) may be set to be slightly long.

### Second Exemplary Embodiment

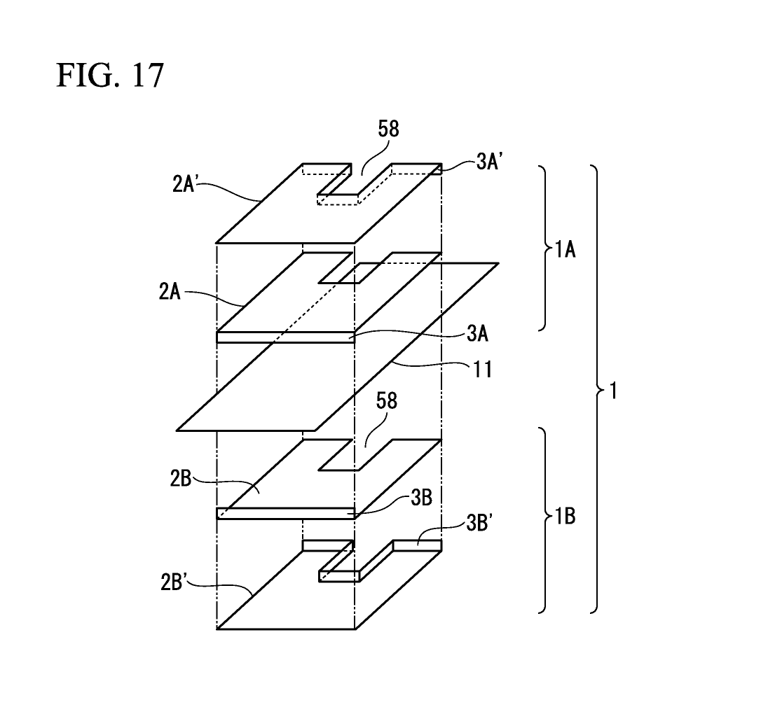

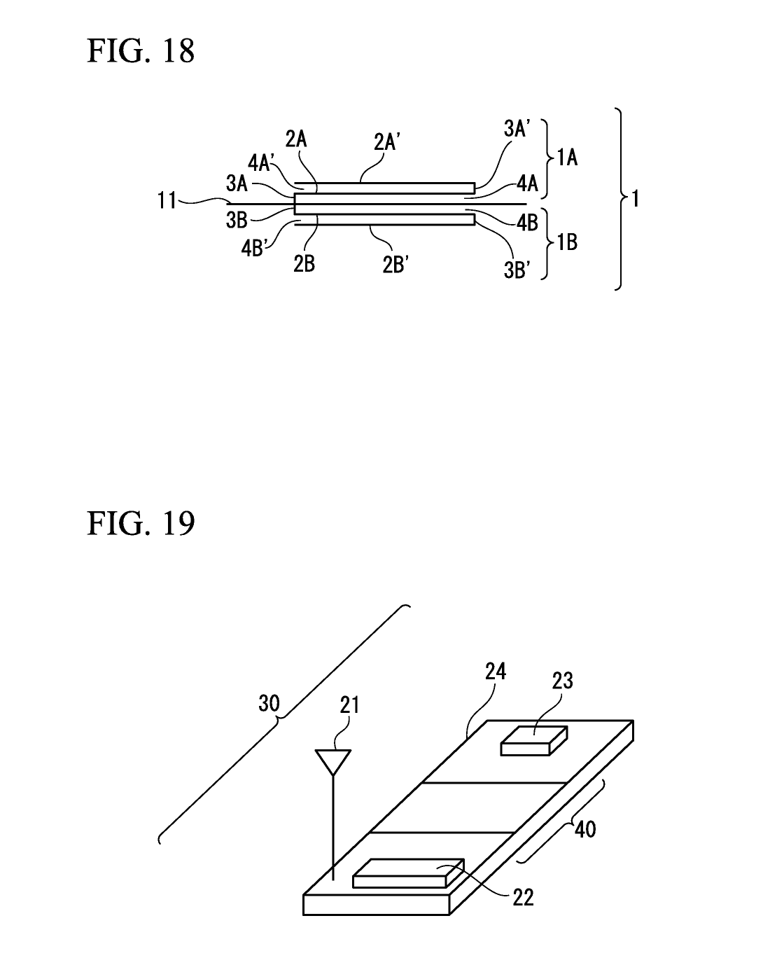

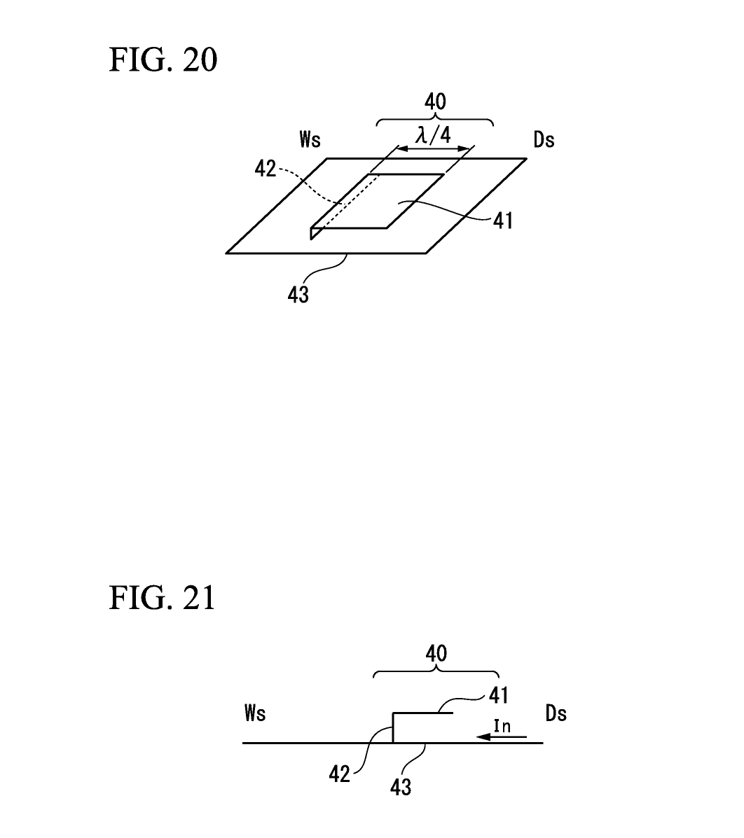

FIGS. 16 to 18 illustrate a noise suppression structure 1 according to a second exemplary embodiment of the present invention. Current control units 1A and 1B constituting the noise suppression structure 1 suppress noise within a board 10 constituting a wireless application device. FIG. 16 is a perspective view illustrating the entire noise suppression structure 1 according to the second exemplary embodiment of the present invention. FIG. 17 is an exploded diagram of the noise suppression structure 1 illustrated in FIG. 16. FIG. 18 is a side view of the noise suppression structure 1 illustrated in FIG. 16.

In the configuration of the first exemplary embodiment, the open ends 4A and 4B of the current control units 1A and 1B are directed toward either the digital circuit unit 23 or the wireless circuit unit 22. On the other hand, in the configuration of the second exemplary embodiment, open ends 4A/4A′ and 4B/4B′ of the current control units 1A and 1B are directed toward both the digital circuit unit 23 and the wireless circuit unit 22 so as to suppress currents that are mixed from the two circuit units.

This configuration, a current suppression configuration is doubly stacked in a layer direction of a board 10 as will be described later. According to this configuration, the open ends 4A and 4B are directed toward the side of the digital circuit unit 23 and the side of the wireless circuit unit 22, and mixing of currents occurring in both the digital circuit unit 23 and the wireless circuit unit 22 is suppressed.

In the noise suppression structure 1 of the second exemplary embodiment, current control units 1A and 1B are disposed between the digital circuit unit 23 and the wireless circuit unit 22. Thereby, electromagnetic coupling between the digital circuit unit 23 and the wireless circuit unit 22 is interrupted and mixing of currents acting as noise flowing into each other between the digital circuit unit 23 and the wireless circuit unit 22 is prevented.

As can be seen with reference to FIGS. 16 to 18, as in the case of the first exemplary embodiment, in order to effectively control a current that flows through a ground layer 11 of the board 10, the noise suppression structure 1 is constituted of the first current control unit 1A disposed at a side of an upper layer of the ground layer 11 and the second current control unit 1B disposed at a side of an lower layer so that the ground layer 11 is interposed therebetween. Configurations and dimensions of the current control units 1A and 1B are exactly the same. The current control units 1A and 1B are disposed to be vertically symmetrical with respect to the ground layer 11.

Specifically, the first current control unit 1A is constituted of two metal planes 2A and 2A′ and short circuit plates 3A and 3A′. The first short circuit plate 3A, the first metal plane 2A, the second short circuit plate 3A′, and the second metal plane 2A′ are disposed in order from the ground layer 11, and continuously connected.

Sizes of the metal planes 2A and 2A′ constituting the first current control unit 1A are the same as a size of the board 10 in the width direction thereof. The metal plane 2A of the first layer and the metal plane 2A′ of the second layer counted from the side of the ground layer 11 are disposed with an interval in a vertical direction. Rectangular notch portions 58 are provided in portions of ends of the metal planes 2A and 2A′.

The notch portions 58 are positioned at the digital circuit unit 23 side Ds. As in the first exemplary embodiment, due to the notch portions 58, a length of the metal plane 2A changes when the wireless circuit unit 22 side Ws is viewed from the digital circuit unit 23 side Ds. In contrast, a length of the metal plane 2A′ changes when the digital circuit unit 23 side Ds is viewed from the wireless circuit unit 22 side Ws.

The notch portions 58 are provided in the vicinity of centers of the metal planes 2A and 2A′. Thus, the length of the metal plane is short in a region of a central portion, and long in regions corresponding to two sides of the board 10 positioned on outer sides.

In the first current control unit 1A, the short circuit plate 3A positioned between the ground layer 11 and the metal plane 2A of the first layer is positioned at the side of the wireless circuit unit 22. The short circuit plate 3A′ positioned between the metal plane 2A of the first layer and the metal plane 2A′ of the second layer is positioned at the side of the digital circuit unit 23. The notch portions 58 are formed in the metal planes 2A and 2A′ and the short circuit plate 3A′ of the side of the digital circuit unit 23. Thereby, the metal surface 2A constitutes a transmission line with the ground layer 11, one end becomes an open end 4A, and the other becomes a short circuit end (short circuit plane) by the short circuit plate 3A.

The short circuit plate 3A′ at the side of the digital circuit unit 23 is disposed along ends of the metal planes 2A and 2A′ at sides of the notch portions 58. Because this short circuit plate 3A′ is connected to the metal plane 2A′, one pair of transmission paths are formed by the metal planes 2A and 2A′ of two layers and the open end 4A′ is directed toward the side of the wireless circuit unit 22.

Likewise, in the second current unit 1B, the short circuit plate 3B positioned between the ground layer 11 and the metal plane 2B of the first layer is positioned at the side of the wireless circuit unit 22. In addition, the short circuit plate 3B′ positioned between the metal plane 2B of the first layer and the metal plane 2B′ of the second layer is positioned at the side Ds of the digital circuit unit 23. The notch portions 58 are formed in the metal planes 2B and 2B′ and the short circuit plate 3B′ at the side Ds of the digital circuit unit 23. Thereby, the metal plane 2B constitutes a transmission line with the ground layer 11, the open end 4B is formed in one end, and a short circuit end (short circuit plane) by the short circuit plate 3B is formed in the other end.

The short circuit plate 3B′ at the side Ds of the digital circuit unit 23 is disposed along ends of the metal planes 2B and 2B′ at the sides of the notch portions 58. This short circuit plate 3B′ is connected to the metal plane 2B′. Thus, one pair of transmission paths are formed by the metal planes 2B and 2B′ of two layers and the open end 4B′ is directed toward the side of the wireless circuit unit 22.

In the case where the notch portions 58 are formed in the second exemplary embodiment, dimensions of the metal planes 2A/2A′ and 2B/2B′ are the same as in FIGS. 4 and 9 described above.

Next, an operation and principle in the noise suppression structure 1 according to the second exemplary embodiment will be described. Shapes and dimensions of the metal planes 2A and 2B of the first layers constituting the current control units 1A and 1B are the same as those of the metal planes 2A and 2B of the first exemplary embodiment illustrated in FIG. 4. In addition, shapes and dimensions of the metal planes 2A′ and 2B′ of the second layers constituting the current control units 1A and 1B are the same as those of the metal planes 2A and 2B of the first exemplary embodiment illustrated in FIG. 9. However, in the metal planes 2A/2A′ and 2B/2B′, ends that connect to the short circuit plates 3A/3A′ and 3B/3B′ are different between the metal planes 2A and 2B of the first layers and the metal planes 2A′ and 2B′ of the second layers.

Lengths of the metal planes 2A/2A′ and 2B/2B′ (the length in the longitudinal direction of the board in this case) are denoted by “L.” A length of a portion excluding the notch portion 58 in the vicinity of a central portion of the metal plane 2A/2A′ or 2B/2B′ is denoted by “S.” In the case of this configuration, as in the case of the first exemplary embodiment, there is a relationship of “L>S.” In addition, “L” and “S” are set at resonant lengths of ¼ wavelength with respect to desired different frequencies f₁ and f₂. That is, L=λ₁/4 and S=λ₂/4 are set (wavelengths λ₁ and λ₂ are wavelengths of the frequencies f₁ and f₂, respectively).

In the noise suppression structure 1 according to the second exemplary embodiment, a transmission line in which a distal end side is short-circuited is formed as described in the first exemplary embodiment. In addition, lengths of the metal planes 2A/2A′ and 2B/2B′ corresponding to the transmission lines correspond to ¼ wavelength. Thus, impedance at the open ends 4A/4A′ and 4B/4B′ directed toward sides of two circuit units has a very high value.

Further, in the noise suppression structure 1 according to the second exemplary embodiment, as in the case of the first exemplary embodiment, transmission paths resonant at two frequencies are formed in one metal plane 2A/2A′ or 2B/2B′. That is, the notch portions 58 are provided in the vicinity of central portions of the metal planes 2A/2A′ and 2B/2B′. With this configuration, transmission paths corresponding to lengths L of the original metal planes 2A/2A′ and 2B/2B′ are formed on outer sides (two sides of the board), and a transmission path corresponding to a length S that is shorter by the amount of the notch portion 58 is formed in the vicinity of the central portion.

The metal planes 2A/2A′ and 2B/2B′ of the outer sides corresponding to the transmission paths of the length L (=λ₁/4) resonate at the frequency f₁. On the other hand, the metal planes 2A/2A′ and 2B/2B′ of the central portions corresponding to the transmission paths of the length S (=λ₂/4) resonate at the frequency f₂. Thus, this configuration effectively operates for two frequency components. Thus, it is possible to obtain the effect of suppression in multi-frequency for a current that flows through the ground layer of the board 10 using this configuration.

As can be seen with reference to FIGS. 4 and 9, the metal plane 2A/2A′ and the metal plane 2B/2B′ used in the second exemplary embodiment have the same shape and dimensions, and are the same in that the notch portions 58 are partially provided. However, the metal planes 2A′ and 2B′ are different from the metal planes 2A and 2B in that positions of the short circuit plates 3A′ and 3B′ are shifted to the sides of the notch portions 58. That is, in the metal planes 2A and 2B, the short circuit plates 3A and 3B are disposed on sides opposite the notch portions 58. On the other hand, in the metal planes 2A′ and 2B′, the short circuit plates 3A′ and 3B′ are disposed along the rectangular notch portions 58.

In the case of this configuration, as can be seen with reference to FIGS. 4 and 9, there are a region of an outer side in which a transmission path corresponding to a resonant frequency f₁ has a length L (=λ₁/4) and a region of a central portion in which a transmission path corresponding to a resonant frequency f₂ has a length S (=λ₂/4).

Thus, although positions of the short circuit plates are different in the metal planes 2A/2A′ and 2B/2B′ of the second exemplary embodiment, high impedance is obtained in two frequency bands at the sides of the open ends 4A/4A′ and 4B/4B′ because a transmission path length is set to a length of ¼ wavelength. As a result, it is possible to obtain the effect of suppression in a wide band for noise currents mixed from the sides of the open ends 4A/4A′ and 4B/4B′.

In the noise suppression structure 1 according to the second exemplary embodiment as described above, the notch portions 58 are provided in the metal planes 2A/2A′ and 2B/2B′ of the current control units 1A and 1B. According to this configuration, it is possible to form transmission paths corresponding to at least two frequencies on one metal plane 2A/2A′ or 2B/2B′ in each of the current control units 1A and 1B. Thereby, for example, the effect of suppression is obtained in at least two frequency bands for a noise current, which is generated from the digital circuit unit 23, flows through the board and mixed into the wireless circuit unit 22, or a noise current, which is generated from the wireless circuit unit 22, flows through the board and mixed into the digital circuit unit 23. As a result, it is possible to effectively achieve multi-frequency correspondence to a noise suppression frequency and band widening (an application to a signal pattern and a power supply layer).

Although an example in which the current control units 1A and 1B are disposed at the upper layer and the lower layer of the ground layer of the board 10 has been described in this exemplary embodiment, it is not limited thereto. As in an actual printed substrate, a signal pattern or a power supply layer (plane) may be disposed on layers of upper sides of the current control units 1A and 1B. In this case, only one of the current control units 1A and 1B at a side on which the signal pattern or the power supply layer is disposed may be used among the first current control units 1A and 1B and the second current control units 1A and 1B between which the ground layer is interposed. For example, in the case of the application to a signal pattern, the signal pattern, a first current suppression mechanism, and a ground layer may be disposed in order from an upper layer of the board 10.

While a linear shape such as a rectangular shape or a V shape has been described as the shape of the notch portion 58 in the exemplary embodiments of the present invention, it is not limited thereto. The notch portion 58 may have a curved shape if multi-frequency correspondence or high frequency correspondence is obtained.

While the digital circuit unit 23, the wireless circuit unit 22, and the antenna unit have been described as circuit units in the exemplary embodiments of the present invention, it is not limited thereto. Because this configuration suppresses the current, it is not limited to only the above-described circuit units if only generating a current. For example, a configuration by the exemplary embodiments of the present invention may be applied to a general circuit unit or device such as an analog circuit unit or large scale integration (LSI).

Although the exemplary embodiments of the present invention have been described above with reference to the drawings, specific configurations are not limited to these exemplary embodiments, and design changes can also be included without departing from the scope of the present invention.

This application is based upon and claims the benefit of priority from Japanese patent application No. 2010-058238, filed Mar. 15, 2010, the disclosure of which is incorporated herein in its entirety by reference.

### INDUSTRIAL APPLICABILITY

The noise suppression structure of the present invention is applicable to electronic/electric equipment including a wireless application device such as a portable phone, a wirelessly equipped personal computer, and a portable information terminal.

### DESCRIPTION OF REFERENCE SYMBOLS

1 Current control unit

1A First current control unit

1B Second current control unit

2A, 2A′, 2B, 2B′ Metal plane

3A, 3A′, 3B, 3B′ Short circuit plate

4A, 4A′, 4B, 4B′ Open end

10 Board

11 Ground layer

21 Antenna unit

22 Wireless circuit unit

23 Digital circuit unit

24 Printed substrate

30 Wireless application device

50 to 58 Notch portion

1. A noise suppression structure comprising a current control unit provided on a ground layer and controlling current, the current control unit comprising:
a metal plane that is provided above the ground layer with an interval therebetween; and
a short circuit plate that is arranged at one end portion of the metal plane, and connects the metal plane and the ground layer,
a notch portion provided in a portion of the metal plane.

2. A noise suppression structure comprising a current control unit provided on a ground layer and controlling current, the current control unit comprising a first current control unit provided on an upper side of the ground layer, and a second current control unit provided on a lower side of the ground layer, the first current control unit and the second current control unit sandwiching the ground layer therebetween, and each of the first and second current control units comprising:
a metal plane that is provided above the ground layer with an interval therebetween; and
a short circuit plate that is arranged at one end portion of the metal plane, and connects the metal plane and the ground layer,
a notch portion provided in a portion of the metal plane.

3. The noise suppression structure according to claim 2, wherein the first and second current control units commonly use the ground layer, and the first and second current control units are arranged in a vertically symmetrical manner.

4. The noise suppression structure according to claim 1, wherein an open end is formed at an other end portion of the metal plane at which the short circuit plate is not provided.

5. The noise suppression structure according to claim 2, wherein the first and second current control units are mounted between circuits serving as noise generation sources.

6. The noise suppression structure according to claim 2, wherein a digital circuit unit is arranged at one end portion of the first and second current control units, and a wireless circuit is arranged at an other end portion of the first and second current control units.

7. The noise suppression structure according to claim 1, wherein the notch portion has a rectangular shape.

8. The noise suppression structure according to claim 1, wherein the notch portion has an inclined end.

9. The noise suppression structure according to claim 8, wherein the notch portion has a V shape.
